(19) United States
(12) Patent Application Publication
(10) Pub. No.: US 2008/0185595 A1
(43) Pub. Date: Aug. 7, 2008

(54) Light emitting device for alternating current source

(75) Inventors: Won Ha Moon, Suwon (KR); Chang Hwan Choi, Sungnam (KR); Hyun Jun Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/068,392

(22) Filed: Feb. 6, 2008

(30) Foreign Application Priority Data
Feb. 6, 2007 (KR) 10-2007-0012111

(51) Int. Cl. H01L 33/00

(52) U.S. Cl. 257/79; 257/E33.045

(57) ABSTRACT

There is provided a light emitting device that can reduce the size of a light emitting device module by using a more simplified light emitting device that directly uses an alternating current source, prevent a decrease in luminous efficiency that is caused due to the use of a separate driving device, solve a problem with an ohmic contact of a p-type electrode, reduce the number of electrodes, and secure a larger area of light emission. A light emitting device for an alternating current source according to an aspect of the invention includes a first conductive type first semiconductor layer, a first electrode formed on the first conductive type first semiconductor layer and electrically connected to the alternating current source, a second conductive type second semiconductor layer formed on the first conductive type first semiconductor layer, a first conductive type third semiconductor layer formed on the second conductive type second semiconductor layer, and a second electrode formed on the third semiconductor layer and electrically connected to the alternating current source. Here, the light emitting device operates in response to a voltage from the alternating current source through the first electrode and the second electrode.

### CROSS-REFERENCE TO RELATED APPLICATIONS

This application claims the priority of Korean Patent Application No. 2007-12111 filed on Feb. 6, 2007, in the Korean Intellectual Property Office, the disclosure of which is incorporated herein by reference.

### BACKGROUND OF THE INVENTION

1. Field of the Invention

The present invention relates to a light emitting device, and more particularly, to a light emitting device that can reduce the size of a light emitting device module by using a more simplified light emitting device that directly uses an alternating current source, prevent a decrease in luminous efficiency that is caused due to the use of a separate driving device, solve a problem with an ohmic contact of a p-type electrode, reduce the number of electrodes, and secure a larger area of light emission.

2. Description of the Related Art

In general, light emitting devices include materials that emit light. For example, like a light emitting diode (LED), a device that uses a diode to which semiconductors are bonded converts energy, generated by combination of electrons and holes, into light and emits light. The light emitting device is widely used as lighting, display devices, and light sources, and development of the light emitting device has been expedited.

In general, a semiconductor junction LED structure has P-type and n-type semiconductor junctions. In the semiconductor junction LED structure, an active layer is formed between both semiconductors such that light having a desired wavelength can be emitted.

FIG. 1 is a cross-sectional view illustrating a light emitting device according to the related art.

A light emitting device 1 includes a substrate 40, an n-type semiconductor 30, an active layer 20, and a p-type semiconductor 10. An n-type electrode 31 and a p-type electrode 11 are formed on the n-type semiconductor layer 30 and the p-type semiconductor layer 30, respectively, and are electrically connected to an external power source in order to apply a voltage. In FIG. 1, a description is made of an example in which the n-type semiconductor layer 30 is first formed on the substrate 40, and then, the active layer 20 and the p-type semiconductor layer 10 are formed thereon. However, after the p-type semiconductor layer is formed on the substrate, and then the active layer and the n-type semiconductor layer may be formed thereon.

When a voltage is applied to the light emitting device 1 through the electrodes, electrons move from the n-type semiconductor layer 30, and holes move from the p-type semiconductor layer 10. Light is emitted by recombination of the electrons and the holes. The light emitting device 1 includes the active layer 20, and light is emitted from the active layer 20. In the active layer 20, light emission of the light emitting device 10 is activated, and a wavelength of the light is controlled to emit light of a desired color.

Here, electrodes need to be formed on the n-type semiconductor layer 30 and the p-type semiconductor layer 10 to provide an electrical connection to the external power source. An appropriate electrode needs to be formed according to a type of each of the semiconductor layers. When the substrate 40 is a sapphire substrate that is non-conductive, the electrode of the n-type semiconductor layer 30 cannot be formed on the substrate 40 but on the n-type semiconductor layer 30.

Referring to FIG. 1, when the n-type electrode 31 is formed on the n-type semiconductor layer 30, parts of the p-type semiconductor layer 10 and the active layer 20 that are formed at the upper side are consumed to form an ohmic contact. The formation of the electrode results in a decrease in area of light emission, and thus luminous efficiency also decreases.

When other semiconductor layers are further formed on the light emitting device, each of the semiconductor layers requires an electrode. The area of light emission of the light emitting device decreases in inverse proportion to the number of electrodes at a predetermined ratio.

Further, when the P-type electrode 11 is formed on the P-type semiconductor layer 10, a kind of heterojunction is formed between a metal and a semiconductor to create a potential barrier such as a Schottky barrier. This may cause a problem in the flow of current from the p-type electrode 11 to the p-type semiconductor layer 10.

In order to drive the light emitting device according to the related art, since commercial power is AC power, it needs to be converted into DC power by using a separate driving device, such as an AD-DC converter circuit or a DC regulator. However, when the separate driving device is used, the luminous efficiency of the light emitting device is considerably reduced.

Therefore, there has been a continuous demand for a light emitting device that has a structure capable of solving the above-described problems, such as a decrease in area of light emission, P-type ohmic contacts, a decrease in luminous efficiency.

### SUMMARY OF THE INVENTION

An aspect of the present invention provides a light emitting device that can reduce the size of a light emitting device module by using a more simplified light emitting device that directly uses an alternating current source, prevent a decrease in luminous efficiency that is caused due to the use of a separate driving device, solve a problem with an ohmic contact of a p-type electrode, reduce the number of electrodes, and secure a larger area of light emission.

According to an aspect of the present invention, there is provided a light emitting device for an alternating current source that operates upon receiving a voltage from the alternating current source, the device including: a first conductive type first semiconductor layer; a first electrode formed on the first conductive type first semiconductor layer and electrically connected to the alternating current source; a second conductive type second semiconductor layer formed on the first conductive type first semiconductor layer; a first conductive type third semiconductor layer formed on the second conductive type second semiconductor layer; and a second electrode formed on the third semiconductor layer and electrically connected to the alternating current source. Here, the light emitting device operates in response to a voltage from the alternating current source through the first electrode and the second electrode.

The first semiconductor layer and the third semiconductor layer may be formed of n-type semiconductors, and the second semiconductor layer may be formed of a p-type semiconductor. The first electrode may be an n-type electrode.

The first semiconductor layer and the third semiconductor layer may be formed of p-type semiconductors, and the second semiconductor may be formed of an n-type semiconductor. The second electrode may be a p-type electrode.

The light emitting device may further include a first active layer formed on the first semiconductor layer to emit light; and a second active layer formed on the second semiconductor layer to emit light.

The first active layer and the second active layer may have different energy bandgaps from each other. Each of the first active layer and the second active layer may comprise one or more energy well layers. The energy well layer may comprise one of a plurality of quantum dots and a plurality of quantum nanorods.

The light emitting device may further include a substrate on which the third semiconductor layer is formed. The substrate may be one of a conductive substrate and a non-conductive substrate. When the substrate is the conductive substrate, the first electrode may be formed on the conductive substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a light emitting device according to the related art.

FIG. 2 is a cross-sectional view illustrating a light emitting device for an alternating current source according to one exemplary embodiment of the present invention.

FIG. 3 is a cross-sectional view illustrating a light emitting device for an alternating current source according to another exemplary embodiment of the present invention.

FIG. 4 is a view illustrating a graph of an I-V curve of a light emitting device according to the embodiment shown in FIG. 1.

FIG. 5 is a cross-sectional view illustrating a light emitting device for an alternating current source according to still another exemplary embodiment of the present invention.

FIG. 6 is a cross-sectional view illustrating a light emitting device for an alternating current source according to yet another exemplary embodiment of the present invention.

### DETAILED DESCRIPTION OF THE PREFERRED EMBODIMENT

Exemplary embodiments of the present invention will now be described in detail with reference to the accompanying drawings.

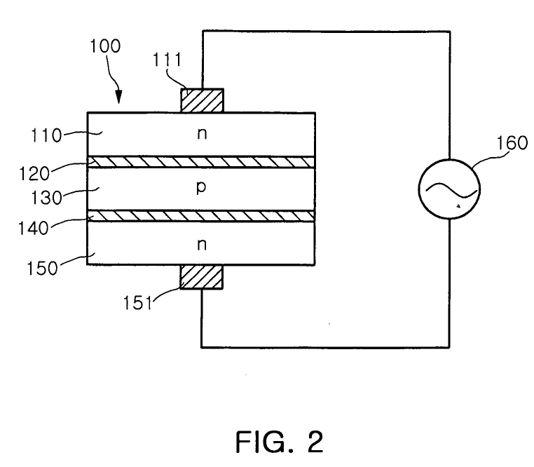

FIG. 2 is a cross-sectional view illustrating a light emitting device for an alternating current source according to one exemplary embodiment of the invention. A light emitting device 100 for an alternating current source includes a first conductive type first semiconductor layer 110, a first electrode 111, a second conductive type second semiconductor layer 130, a first conductive type third semiconductor layer 150, and a second electrode 151. The first electrode 111 is formed on the first conductive type first semiconductor layer 110 and electrically connected to an alternating current source 160. The second conductive type second semiconductor layer 130 is formed on the first conductive type first semiconductor layer 110. The first conductive type third semiconductor layer 150 is formed on the second conductive type second semiconductor layer 130. The second electrode 151 is formed on the third semiconductor layer 150 and electrically connected to the alternating current source 160.

In FIG. 2, the first conductive type first semiconductor layer 110 and the third semiconductor layer 150 are n-type semiconductor layers, and the second conductive type second semiconductor layer 130 is a p-type semiconductor layer. The first conductive type first semiconductor layer 110, the second conductive type second semiconductor layer 130, and the first conductive type third semiconductor layer 150 have an n-p-n junction structure.

Each of the semiconductor layers may be composed of an inorganic semiconductor, such as a GaN-based semiconductor, a ZnO-based semiconductor, a GaAs-based semiconductor, a GaP-based semiconductor, and a GaAsP-based semiconductor. The semiconductor layer may be formed by using molecular beam epitaxy (MBE) or the like. In addition, the semiconductor layers may be formed of any one of semiconductors, such as a III-V semiconductor, a II-VI semiconductor, and Si.

The first conductive type first semiconductor layer 110 and the third semiconductor layer 150 are formed of n-type semiconductors, and are n-doped. The second conductive type second semiconductor layer 130 is formed of a p-type semiconductor, and is p-doped. It will be apparent that doping concentration of each of the impurities can be selected according to activation of each of the impurities by those skilled in the art.

In the light emitting device 100 for the alternating current source according to the embodiment of the invention, the first electrode 111 is an n-type electrode. The light emitting device 100 for the alternating current source uses an alternating current source to receive a voltage necessary for light emission. The first electrode 111 makes an electrical connection for this. An electrode is not formed on the second conductive type second semiconductor layer 130 nor connected to the alternating current source 160.

An electrode is not formed on the second semiconductor layer 130. That is, since the second semiconductor layer 130 is formed of the p-type semiconductor, it is expected that a p-type electrode is formed on the second semiconductor layer 130. However, the light emitting device 100 for the alternating current source according to the exemplary embodiment of the invention receives AC power and can emit light even though the electrode is not formed on the second semiconductor layer 130. Therefore, the electrode does not need to be formed on the second semiconductor layer 130. Therefore, difficulties in forming the p-type electrode, that is, the problem in the p-type ohmic contact can be solved.

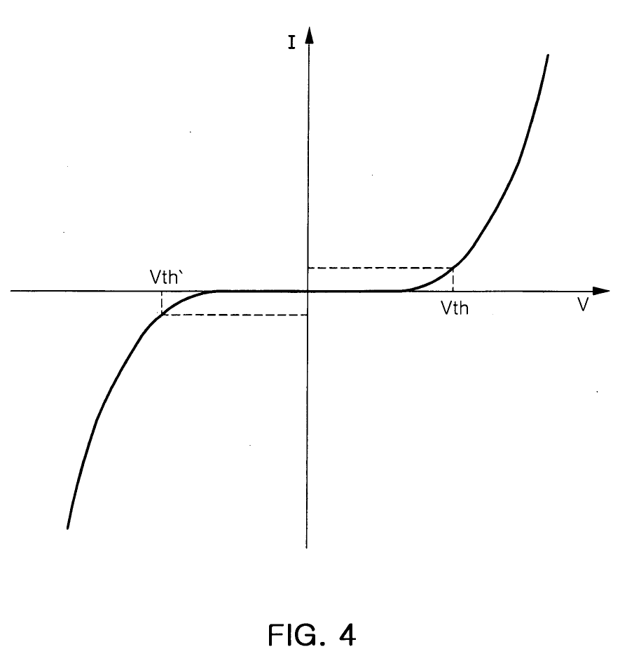

The alternating current source 160 has a predetermined frequency and applies a current that changes. Therefore, in the light emitting device 100 for the alternating current source, a current flows in a predetermined direction during a predetermined period, and the current flows in the other direction during a next period. When a voltage is applied to the first semiconductor layer 110 toward the second semiconductor layer 130, light is emitted from the first active layer 120. Then, light is emitted from the second active layer 140. Further, when the current changes, a voltage is applied to the third semiconductor layer 150 toward the second semiconductor layer 130. At this time, light is first emitted from the second active layer 140. An I-V curve with respect to light emission will be described below with reference to FIG. 4.

In this way, when the light emitting device 100 for the alternating current source according to the exemplary embodiment of the invention is used, it is possible to realize a light emitting device by directly using an alternating current source without the need for a separate driving device, such as an AC-DC converter.

The light emitting device 100 for the alternating current source may further include a first active layer 120 and a second active layer 140. The first active layer 120 is formed on the first conductive type first semiconductor layer 110 and emits light. The second active layer 140 is formed on the second conductive type second semiconductor layer 130 and emits light.

Each of the first active layer 120 and the second active layer 140 is a layer at which light emission is activated. Each of the active layers 120 and 140 is formed of a material that has a smaller energy bandgap than that of each of the semiconductor layers. For example, when each of the first semiconductor layer 110 and the second semiconductor layer 130 is a GaN layer, the first active layer 120 may be formed of InGaN that has a smaller energy bandgap than GaN. At this time, in terms of characteristics of the active layer, the active layer is not preferably doped with impurities. The wavelength of emitting light may be controlled by adjusting a mole ratio of constituents.

According to the active layers, energy wells appear in the entire energy-band diagram of the light emitting device. Electrons and holes from the respective semiconductor layers are moving and trapped within the energy wells, which results in more efficient light emission.

A wavelength of light from the first active layer 120 may be different from a wavelength of light from the second active layer 140. Since both of the active layers 120 and 140 have different wavelengths of light, colors of light are also different. The wavelength of the light may be controlled by controlling materials that are contained in both active layers 120 and 140.

When each of the active layers is formed of a direct transition material, a wavelength of light emitted can be obtained by Equation 1.

λ=1240/E_{g} [Equation 1]

Here, A refers to the emission wavelength (nm) and E_{g} refers to an energy bandgap eV.

According to Equation 1, when an active material having an appropriate energy bandgap is used, it is possible to obtain light of desired color by controlling a wavelength of light.

Therefore, light that is finally emitted from the light emitting device 100 for the alternating current source will indicate a color obtained by synthesizing light from the active layers 120 and 140. Here, light of mixed colors according to the frequency of the applied AC power may be emitted.

Further, each of the active layers 120 and 140 may include a plurality of energy well layers. Here, each of the active layers 120 and 140 including the plurality of energy well layers has an energy barrier layer between the energy well layers to separate energy well structures from each other. In this way, a quantum confinement effect can be more effectively obtained.

It will be apparent that the number of repeating the energy well layer-energy barrier layer structures can be appropriately selected by those skilled in the art in consideration of luminous efficiency.

Preferably, each of the energy well layers included in each of the active layers 120 and 140 includes either a plurality of quantum dots or a plurality of quantum nanorods.

The quantum dots are spots that have a diameter of a few nanometers. The quantum dots are three-dimensionally included in each of the active layers 120 and 140. Compared with a case in which active materials are distributed in the form of layers, the quantum dots produce a stronger quantum confinement effect. Therefore, the motion of electrons and holes can be effectively confined to thereby increase light-emission activation efficiency.

Similarly, the nanoscale quantum nanorods indicate active materials having a rod shape in the range of a few nanometers to tens of nanometers. The quantum nanorods may be uniformly distributed within each of the active layers 120 and 140, and produce a strong quantum confinement effect like the quantum dots.

When low-dimensional structures, such as the quantum dots and the quantum nanorods, are formed, it can be expected that the quantum effect of each of the active layers 120 and 140 is increased. That is, electrons and/or holes moving within the nanostructures are more effectively confined within the nanostructures, which enables more effective recombination.

As a method of forming the quantum nanorods, there are two methods: a top-down process and a bottom-down process.

According to the top-down process, materials that are used to form quantum nanorods are etched to form nanoscale nanorods. However, the nanoscale nanorods are limited to tens of nanometers. Further, as the size of the material decreases, the manufacturing costs increase. Therefore, in recent years, the bottom-down process has been developed.

Examples of the bottom-down process may include use of an anodic aluminum oxide (AAO) template and vapor-liquid-solid (VLS) phase synthesis.

The reason why aluminum is used in a method using the AAO template is that the aluminum causes the formation of self-organized pores during an oxidization process of forming an aluminum oxide.

In this case, the diameter of the formed pores has a length of a few micrometers (μm) and has a diameter in the range of tens to a few hundred nanometers (nm) according to the voltage and the concentration of acidic solutions in the oxidization process of the aluminum. When a different material is filled in the pore by using the AAO template according to physical and chemical deposition methods, it is possible to produce a quantum nanorod corresponding to the diameter and length of the pore.

The VLS phase synthesis is the most definite method of forming a large amount of single crystal quantum nanorods among vapor phase methods. First, a reactant in a vapor state is dissolved in a droplet of a metal catalyst of nanometer size. In this way, a core is generated, and a single-crystal rod starts to grow. The growth continues to form a quantum nanorod.

As described above, when the active layers 120 and 140 are formed to have the desired structures of quantum dots and quantum nanorods, the surface area of light emission increases to thereby increase luminous efficiency.

When including the quantum dots and the quantum nanorods, the active layers 120 and 140 may further include insulating materials. The insulating materials are filled between the plurality of quantum dots or the plurality of quantum nanorods, and control them so that the flow of electrons and holes only includes the quantum dots and the quantum nanorods.

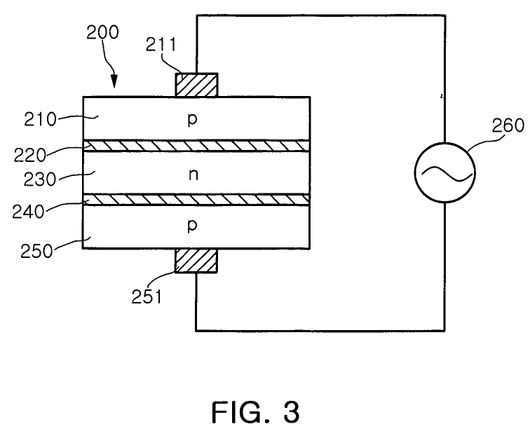

FIG. 3 is a cross-sectional diagram illustrating a light emitting device for an alternating current source according to another exemplary embodiment of the present invention.

A light emitting device 200 for an alternating current source according to another exemplary embodiment of the invention includes a first conductive type first semiconductor layer 210 and a third semiconductor layer 250, which are p-type semiconductor layers, and a second conductive type second semiconductor layer 230 that is an n-type semiconductor layer. The first conductive type first semiconductor layer 210, the second conductive type second semiconductor layer 230, and the third semiconductor layer 250 have a p-n-p junction structure.

The light emitting device 200 for the alternating current source, shown in FIG. 3, has the same structure as the light emitting device 100 for the alternating current source, shown in FIG. 2, except for the following. The first conductive type first semiconductor layer 210 and the third semiconductor layer 250 are formed of p-type semiconductors, and the second conductive type second semiconductor layer 230 is formed of an n-type semiconductor. P-type electrodes are formed on the first and third semiconductor layers. Thus, a description of the same components will be omitted.

In the light emitting device 200 for the alternating current source, when a voltage is applied from an alternating current source 260, current flows from the first conductive type first semiconductor layer 210 toward the second conductive type second semiconductor layer 230. Further, light is emitted from the first active layer 220, and then, light is emitted from the second active layer 240. After a predetermined period of the alternating current source 260, light is emitted from the second active layer 240 first, and then, light is emitted from the first active layer 220.

Since the first conductive type first semiconductor layer 210 and the third semiconductor layer 250 are formed of the p-type semiconductors, the light emitting device 200 for the alternating current source according to the embodiment of the invention includes a first electrode 211 and a second electrode 251 that are p-type electrodes. Therefore, while the light emitting device 100 for the alternating current source, shown in FIG. 2, solves the ohmic contact problem of the p-type electrode, the light emitting device 200 for the alternating current source, shown in FIG. 3, does not solve the problem of the p-type ohmic contact because the device 200 includes the p-type electrode, not the n-type electrode. Still, the alternating current source 260 can be used without a separate driving device.

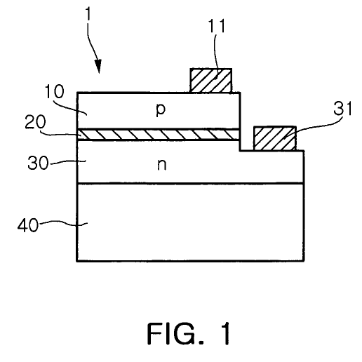

FIG. 4 is a view illustrating a graph of an I-V curve according to the light emitting device according to the embodiment shown in FIG. 1. This will be described with reference to FIGS. 2 and 4.

When a voltage that is applied from the alternating current source 160 increases in a positive direction and reaches a predetermined threshold value Vth, a current flowing through the light emitting device 100 for the alternating current source significantly increases. The voltage is applied through the first electrode 111. Light starts to be emitted from the first active layer 120 between the first conductive type first semiconductor layer 110 and the second semiconductor layer 130. Further, light starts to be emitted from the second active layer 140 between the second conductive type second semiconductor layer 130 and the third semiconductor layer 150.

On the contrary, when the voltage that is applied from the alternating current source increases in a negative direction and reaches a predetermined voltage Vth′, a current flowing through the light emitting device 100 for the alternating current source significantly increases in the negative direction. In this case, since values are the same as those above described in the other direction, light is emitted along the other direction. That is, light starts to be emitted from the second active layer 140 first, and then, light starts to be emitted from the first active layer 120.

The two types of emissions alternately occur according to the frequency of the alternating current source 160. Colors of light generated according to the emissions are mixed according to the frequency to produce a mixed color.

Therefore, since the light emitting device 100 for the alternating current source directly uses the alternating current source, it can emit light without using the separate AC-DC converter. In this way, a light emitting device having higher luminous efficiency can be realized.

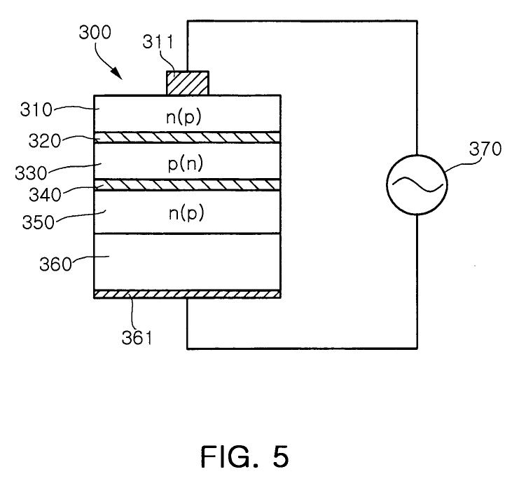

FIG. 5 is a cross-sectional view illustrating a light emitting device for an alternating current source according to still another exemplary embodiment of the invention.

A light emitting device 300 for an alternating current source, shown in FIG. 5, has the same structure as the light emitting device 100 for the alternating current source, shown in FIG. 2, except for the following. The light emitting device 300 for the alternating current source includes a first conductive type first semiconductor layer 310 and a first conductive type third semiconductor layer 350, which are semiconductor layers having the same polarity (n or p), a second conductive type second semiconductor layer 330 that is doped of opposite polarity (p or n) to the semiconductor layers 310 and 350, a substrate 360 on which the third semiconductor layer 350 is formed, and a second electrode 361 that is formed on the substrate 360, not on the third semiconductor layer 350. Thus, a description of the same components will be omitted.

The light emitting device 300 for the alternating current source may further include the substrate 360 on which the third semiconductor layer 350 is formed. In FIG. 5, the substrate 360 is a conductive substrate. The conductive substrate may be composed of any one of metal, alloys, Si, and SiC. Since the substrate 360 is the conductive substrate, an ohmic contact does not need to be formed on the third semiconductor layer 350 to form the electrode. Since a region where light is emitted can be secured except for a region where the first electrode 311 is formed, high luminous efficiency can be expected.

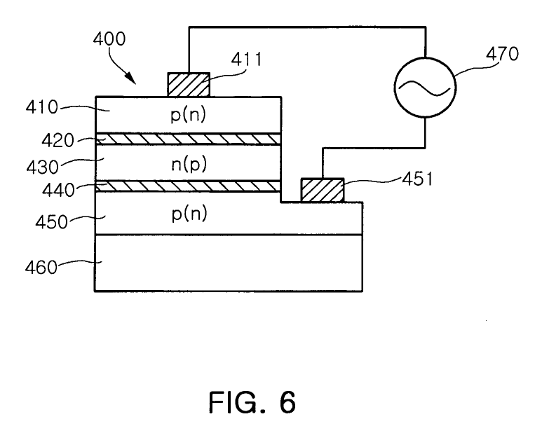

FIG. 6 is a cross-sectional view illustrating a light emitting device for an alternating current source according to yet another exemplary embodiment of the present invention.

A light emitting device 400 for an alternating current source, shown in FIG. 6, has the same structure as the light emitting device 100 for the alternating current source except for the following. The light emitting device 400 for the alternating current source includes a first conductive type first semiconductor layer 410 and a first conductive type third semiconductor layer 450, which are semiconductor layers having the same polarity (n or p), a second conductive type second semiconductor layer 430 that is doped of opposite polarity (p or n) to the first and third semiconductor layers 410 and 450, and a substrate 460 on which the third semiconductor layer 450 is formed. Thus, a description of the same components will be omitted.

The light emitting device 400 for the alternating current source according to yet another exemplary embodiment of the invention may further include the substrate 460 on which the third semiconductor layer 450 is formed. In FIG. 6, the substrate 460 is a non-conductive substrate. A sapphire substrate can be used as the non-conductive substrate.

Since the substrate 460 is the non-conductive substrate, an ohmic contact is formed to form a second electrode 451 on the third semiconductor layer 450. However, since the second electrode 451 does not need to be formed on the second conductive type second semiconductor layer 430, the number of electrodes decreases when compared with the light emitting device according to the related art, and the decrease in area of light emission, caused due to the formation of electrodes, can be prevented.

When it comes to the selection of the substrates as shown in FIGS. 5 and 6, the conductive substrate is formed of expensive materials and is manufactured according to a difficult process, thereby increasing manufacturing costs. However, since electrodes can be formed on the conductive substrate, luminous efficiency increases. On the other hand, since electrodes need to be formed on the semiconductor layers, the non-conductive substrate adversely affects the luminous efficiency. However, the non-conductive substrate is formed of cheap materials and is manufactured according to a relatively simple process. Therefore, those skilled in the art may appropriately select one of the substrates.

As set forth above, according to exemplary embodiments of the invention, when the light emitting device is driven by using an alternating current source, since the light emitting device does not need to use a separate driving device, such as an AD-DC converter, the size of a light emitting device module decreases, and a decrease in luminous efficiency can be prevented because the separate driving device is not used.

Further, when an n-p-n junction device is used as the light emitting device for the alternating current source, since a p-type electrode does not need to be formed, a problem with an ohmic contact between a p-type electrode and a p-type semiconductor layer can be prevented.

Further, since an electrode does not need to be connected to each of the semiconductor layers, the number of electrodes used is reduced. Since the electrode is not necessarily formed on each of the semiconductor layers, it is possible to secure a wider area of light emission. In addition, since quantum nanorod structures are used in active layers, the area of light emission increases to thereby increase the luminous efficiency.

While the present invention has been shown and described in connection with the exemplary embodiments, it will be apparent to those skilled in the art that modifications and variations can be made without departing from the spirit and scope of the invention as defined by the appended claims.

What is claimed is:

1. A light emitting device for an alternating current source that operates upon receiving a voltage from the alternating current source, the device comprising:
a first conductive type first semiconductor layer;
a first electrode formed on the first conductive type first semiconductor layer and electrically connected to the alternating current source;
a second conductive type second semiconductor layer formed on the first conductive type first semiconductor layer;
a first conductive type third semiconductor layer formed on the second conductive type second semiconductor layer; and
a second electrode formed on the third semiconductor layer and electrically connected to the alternating current source,
wherein the light emitting device operates in response to a voltage from the alternating current source through the first electrode and the second electrode.

2. The light emitting device of claim 1, wherein the first semiconductor layer and the third semiconductor layer are formed of n-type semiconductors, and the second semiconductor layer is formed of a p-type semiconductor.

3. The light emitting device of claim 2, wherein the first electrode is an n-type electrode.

4. The light emitting device of claim 1, wherein the first semiconductor layer and the third semiconductor layer are formed of p-type semiconductors, and the second semiconductor is formed of an n-type semiconductor.

5. The light emitting device of claim 4, wherein the second electrode is a p-type electrode.

6. The light emitting device of claim 1, further comprising:
a first active layer formed on the first semiconductor layer to emit light; and
a second active layer formed on the second semiconductor layer to emit light.

7. The light emitting device of claim 6, wherein the first active layer and the second active layer have different energy bandgaps from each other.

8. The light emitting device of claim 6, wherein each of the first active layer and the second active layer comprises one or more energy well layers.

9. The light emitting device of claim 8, wherein the energy well layer comprises one of a plurality of quantum dots and a plurality of quantum nanorods.

10. The light emitting device of claim 1, further comprising: a substrate on which the third semiconductor layer is formed.

11. The light emitting device of claim 1, wherein the substrate is one of a conductive substrate and a non-conductive substrate.

12. The light emitting device of claim 11, wherein when the substrate is the conductive substrate, the first electrode is formed on the conductive substrate.
